(19) United States
(12) Patent Application Publication
(10) Pub. No.: US 2003/0015962 A1
(43) Pub. Date: Jan. 23, 2003

(54) Electroluminescent panel having controllable transparency

(76) Inventors: Matthew Murasko, Manhattan Beach, CA (US); Patrick J. Kinlen, Fenton, MO (US)

Correspondence Address: LATHROP & GAGE LC, 2345 GRAND AVENUE, SUITE 2800, KANSAS CITY, MO, 64108, US

(21) Appl. No.: 10/183,206

(22) Filed: Jun. 27, 2002

Related U.S. Application Data
(60) Provisional application No. 60/301,204, filed on Jun. 27, 2001.

(51) Int. Cl. H05B 33/02

(52) U.S. Cl. 313/509

(57) ABSTRACT

The present invention provides electroluminescent devices including electroluminescent panels that are transparent until illuminated.

### RELATED APPLICATIONS

This application is an application which claims the priority of prior patent application serial No. 60/301,204, filed Jun. 27, 2001, entitled Electroluminescent Panel Having Controllable Transparency, which is hereby incorporated by reference into this application.

### BACKGROUND OF THE INVENTION

1. Field of the Invention

This invention relates generally to electroluminescent light emitting panels, and more specifically, to an electroluminescent light emitting panel that is transparent until illuminated.

Problem

Electroluminescent (EL) panels are surface-area light sources wherein light is produced by exciting an electroluminescent material, typically by an electric field. Previously existing EL panels employ a suitable phosphor placed between two metallic sheet surfaces forming two electrode layers, only one of which may be transparent. An electrical current is applied to the electrode layers in order to excite the phosphor material to produce light. Such electroluminescent panels are typically formed of elongate, flexible strips of laminated material that are adaptable for use in many different shapes and sizes.

Some of the reasons for using electroluminescent panels include the ability to provide sources of uniform light in various bright colors, and the ability to emit cool light without creating noticeable heat or substantial current drain. However, previous EL panels are not transparent, and therefore cannot transmit light nor function as windows.

Solution

The present electroluminescent panel includes an illumination layer comprising light emitting polymers or other electroluminescent (EL) material that is transparent until energized by an electrical potential applied to the EL material to cause it to emit light. When the panel is appropriately energized, the panel emits light from the illumination layer. When emitting light, the illumination layer area becomes essentially non-light-transmissive.

The present invention includes the use of printed or deposited conductive inks such as copper, nickel, or platinum, which have high conductivity and high transparency in thin layers. The process for fabricating the present electroluminescent panels includes printing a palladium catalyst onto the surface, drying the catalyst for activation, followed by immersion of the coated substrate into a copper plating solution bath, rinsing and drying. The concentration of catalyst, thickness of the catalyst film, and immersion time in the copper plating bath determine the thickness of the metal deposited.

In contrast to existing electroluminescent (EL) panels, EL panels fabricated in accordance with the presently described process are transparent in the absence of an applied electrical potential, which makes them amenable to a wide range of applications. These panels may be used in practically any application, indoors or outdoors, where windows or display panels are presently used. The presently described technology may also be applied to printing patterns of electrodes for printable batteries, fuel cells and solar cells. Advantages of the technology are high conductivity and transparency at low cost with respect to conductive inks.

### BRIEF DESCRIPTION OF THE DRAWINGS

FIG. 1A is a diagram of an electroluminescent panel in accordance with the present invention, showing the panel in an unenergized state;

FIG. 1B is a diagram of the electroluminescent panel of FIG. 1A, showing the panel in an energized state; and

FIG. 2 is a flowchart illustrating an exemplary method for fabricating an electroluminescent panel in accordance with the embodiment of FIGS. 1A/1B.

### DETAILED DESCRIPTION

U.S. patent application Ser. No. 09/815,078 filed Mar. 22, 2001, for an “Electroluminescent Multiple Segment Display Device”, discloses a system for fabricating an electroluminescent display device from materials including light emitting polymers (LEPs), the disclosure of which is herein incorporated by reference. The present electroluminescent panel includes an illumination layer comprising light emitting polymers (LEPs) or other electroluminescent (EL) material that is transparent until energized by an electrical potential applied to the EL material to cause it to emit light. When the panel is appropriately energized, the panel emits light from the illumination layer, which may be patterned to allow certain areas of the panel to be illuminated. When emitting light, the illumination layer area becomes essentially non-light-transmissive. The areas not patterned or coated with electroluminescent material (if any) remain transparent, regardless of the state of the illumination layer.

Suitable light emitting polymers include polypyridine, poly(p-phenylene vinylene) or poly[2-methoxy-5-(2′-ethylhexyloxy)-1,4-phenylenevinylene], poly[2-methoxy-5-(2-ethylhexyloxy)-1,4-phenylene-vinylene];poly[(2-methoxy-5-(2-ethylhexyloxy)-1,4-phenylene-vinylene)-alt-co-(4,4′-biphenylene-vinylene)]; poly[(9,9-dioctyl-2,7-divinylenefluorenylene)-alt-co-(9,10-anthracene)]; poly[(9,9-dioctyl-2,7-divinylenefluorenylene)-alt-co-(4,4′-biphenylene)] ;poly[{9,9-dioctyl-2,7-divinylene-fluorenylene}-alt-co-{2-methoxy-5-(2-ethyl-hexyloxy)-1,4-phenylene}]; poly[{9,9-dioctyl-2,7-bis(2-cyanovinylene-fluorenylene}-alt-co-{2-methoxy-5-(2-ethyl hexyloxy)-1,4-phenylene}]; poly[2-methoxy-5-(2-ethylhexyloxy)-1,4-(1-cyanovinylenephenylene)];poly[{9,9-dihexyl-2,7-bis(1-cyanovinylene)fluorenylene}-alt-co-{2,5-bis(N,N′-diphenylamino)-1,4-phenylene}]; poly[{9-ethyl-3,6-bis(2-cyanovinylene)carbazolylene)}-alt-co-{2-methoxy-5-(2-ethylhexyloxy)-1,4-phenylene}]; poly[(9,9-di(2-ethylhexyl)-fluorenyl-2,7-diyl)-co(N, N′-diphenyl)-N,N′-di-(p-butyl phenyl)-1,4-diaminobenzene]; poly[2-(6-cyano-6-methylheptyloxy)-1,4-phenylene);poly[{9,9-dioctylfluorenyl-2,7-diyl}-co-{1,4-(2,5-dimethoxy)benzene}]; poly[{9,9-dioctylfluorenyl-2,7-diyl}-co-{1,4-(2,5-dimethoxy)benzene}]; poly[(9,9-dioctylfluorenyl-2,7-diyl)-co-(1,4-ethylenylbenzene)]; poly[(9,9-dioctylfluorenyl-2,7-diyl)-co-(1,4-diphenylene-vinylene-2-methoxy-5-{2-ethylhexyloxy}-benzene)]; poly[(9,9-dihexylfluorenyl-2,7-divinylenefluorenylene)]; poly[(9,9-dihexyl-2,7-(2-cyanodivinylene)fluorenylene)]; poly[(9,9-dioctylfluorenyl-2,7-diyl)-co-(1,4-vinylenephenylene)]; poly[(9,9-dioctylfluorenyl-2,7-diyl)-co-(1,4-vinylenephenylene)]; poly(9,9-dioctylfluorenyl-2,7-diyl; poly(9,9-dihexylfluorenyl-2,7-diyl); poly[9,9-di-(2-ethylhexyl)-fluorenyl-2,7-diyl]; poly[(9,9-dioctylfluorenyl-2,7-diyl)-co-(N,N′-diphenyl)-N,N′-di(p-butyloxyphenyl) -1,4-diaminobenzene)];poly[(9,9-dioctylfluorenyl-2,7-diyl)-alt-co-(N,N′-diphenyl)-N,N′-di(p-butyloxy-phenyl)1,4diaminobenzene)]; poly[(9,9-dihexylfluorenyl-2,7-diyl)-co-(1,4-benzo-{2,1′,3}-thiadiazole)]; poly[(9,9-dihexylfluorenyl-2,7-diyl)-alt-co-(9,10-anthracene)]; poly[(9,9-dioctylfluorenyl-2,7-diyl)-alt-co-(N,N′-bis{4-butylphenyl}-benzidine-N,N′-{1,4-diphenylene})]; poly[(9,9-dihexylfluorenyl-2,7-diyl)-alt-co-(2-methoxy-5-{2-ethylhexyloxy}-1,4-phenylene)]; poly[(9,9-dihexylfluorenyl-2,7-diyl)-co(9, ethyl-3,6-carbazole)]; poly[(9,9-dihexylfluorenyl-2,7-diyl)-alt-co-(9, ethyl-3,6-carbazole)]; poly[(9,9-dihexylfluorenyl-2,7-diyl)-alt-co-(9,9′-spirobifluorene-2,7-diyl]; poly[(9,9-dihexylfluorenyl-2,7-diyl)-co-(2,5-p-xylene)]; poly[(9,9-dihexylfluorenyl-2,7-diyl)-co-(3,5-pyridine)]; poly[(9,9-dihexylfluorenyl-2,7-diyl)-co-(1,4-phenylene)]; poly[(9,9-dihexylfluorenyl-2,7-diyl)-alt-co-(9,9-di-{5-pentanyl}-fluorenyl-2′,7′-diyl; poly[(9,9-dihexylfluorenyl-2,7-diyl)-co-(6,6′{2,2′-bipyridine})]; poly[(9,9-dihexylfluorenyl-2,7-diyl)-co-(6,6′-{2,2′: 6′,2″-terpyridine})]; and poly[(9,9-dihexylfluorenyl-2,7-diyl)-co-(N,N′bis{p-butylphenyl}-1,4-diamino phenylene)], all of which are commercially available from American Dye Source, Inc.

In an alternative, LEP particles may comprise OLEDs (organic light emitting devices), which includes organic and inorganic complexes, such as tris(8-hydroxyquinolato) aluminum; tetra(2-methyl-8-hydroxyquinolato) boron; lithium salt; 4,4′-bis(9-ethyl-3-carbazovinylene)-1,1′-biphenyl; 9,10-di[(9-ethyl-3-carbazoyl)-vinylenyl)]-anthracene; 4,4′-bis(diphenylvinylenyl)-biphenyl; 1,4-bis(9ethyl-3-carbazovinylene)-2-methoxy-5-(2-ethylhexyloxy)benzene; tris(benzoylacetonato)mono(phenanthroline) europium (III); tris(dibenzoylmethane)mono(phenanthroline) europium (III); tris(dibenzoylmethane)mono(5-aminophenanthroline)europium (III); tris(dinapthoylmethane)mono(phenanthroline) europium (III); tris(biphenoylmethane)mono(phenanthroline) europium (III); tris(dibenzoylmethane)mono(4,7-diphenyl phenanthroline)europium (III); tris(dibenzoylmethane)mono(4,7-dimethyl-phenanthroline)europium (III); tris(dibenzoylmethane)mono(4,7-dihydroxy-phenanthroline)europium (III); tris(dibenzoylmethane)mono(4,7-dihydroxyloxy-phenanthroline)europium (III); lithium tetra(2-methyl-8-hydroxyquinolinato) boron ; lithium tetra(8-hydroxyquinolinato) boron; 4,4′-bis(9-ethyl-3-carbazovinylene)-1,1′-biphenyl; bis(8-hydroxyquinolinato)zinc; bis(2-methyl-8-hydroxyquinolinato)zinc; Iridium (III) tris(2-phenylpyridine); tris(8-hydroxyquinoline)aluminum; and tris[1-phenyl-3methyl-4-(2,2-dimethylpropan-1-oyl)-pyrazolin-5-one]-terbium, many of which are commercially available from American Dye Source, Inc.

One of the configurations employed for present electroluminescent (EL) panels utilizes a transparent substrate upon which is printed in turn a transparent rear electrode, a transparent dielectric layer, an illuminating layer (for example, a light emitting polymer), a transparent front electrode, and a silver (or other electrically conductive material) front electrode lead.

The present invention includes the process of printing or depositing conductive inks by way of any suitable printing method including screen printing, hand printing, ink jetting, and electrolessly plating, wherein said conductive inks may include copper, nickel, or platinum, which have high conductivity and high transparency in thin layers. The process for fabricating the present electroluminescent panels includes printing or depositing a catalyst onto a substrate, drying the catalyst for activation, followed by immersion of the coated substrate into a copper plating solution bath, rinsing, and drying. The concentration of catalyst, thickness of the catalyst film, and immersion time in the appropriate metal plating bath determine the thickness of the metal deposited. It was observed that thin coatings of electrically conductive materials including copper and conductive polymers (for example, PDOT, polyaniline, polypyrrole, and the like) are transparent and may be used to form transparent electrodes in an electroluminescent stack, whereas thicker films may be used as front and rear electrode leads in the panels.

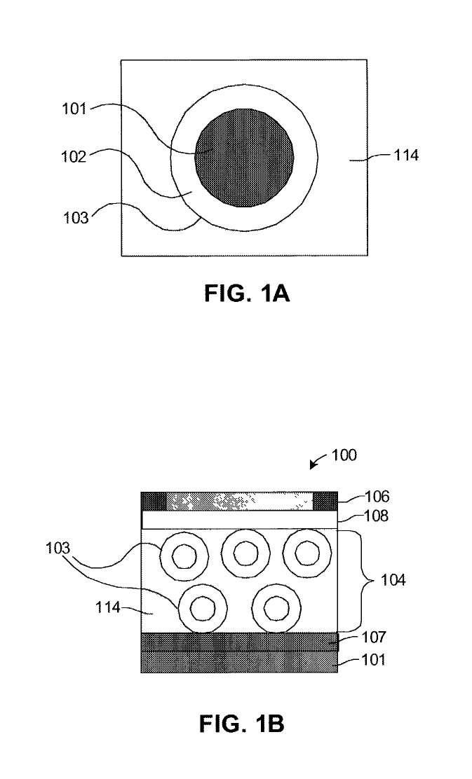

FIG. 1A is a schematic illustration of an exemplary embodiment of an electroluminescent illumination panel 100 comprising a substrate 101, a rear electrode layer 102, a dielectric layer 103, an illumination layer 104, an electrically conductive layer 105, and a front outlining electrode lead (‘front electrode’) 106. As shown in FIG. 1A, in a non-energized state (i.e., when no power is applied), panel 100 is essentially transparent, and allows light to pass through the panel in both directions, as indicated by arrows 110a and 110b. In an alternative embodiment, an electrically conductive layer 105, and a front outlining electrode lead (‘front electrode’) 106 may be combined.

FIG. 1B is a schematic illustration of electroluminescent illumination panel 100 when an electrical potential is applied across rear electrode 102 and conductive layer 105. In operation, an electrical potential is applied across electrodes 102 and 105 to cause illumination of panel 100. The applied voltage may be either AC or DC, depending on the type of material used in illumination layer 104. Voltage is applied to rear electrode 102 via lead 112, and to front electrode 105 via lead 113, which is electrically connected to front electrode by front outlining electrode 106. The electrical connections from the power source or controller (not shown) to leads 112/113 are shown as leads 112a/113a.

When the appropriate electrical power is applied to panel 100, illumination layer 104 emits light in both directions, as indicated by arrows 111. At the same time, incident light from either direction, shown by arrows 110c and 110d, is reflected and/or absorbed by illumination layer 104 to effectively block the light from passing through panel 100, or through areas of the panel containing electroluminescent material, if the illumination layer has been patterned.

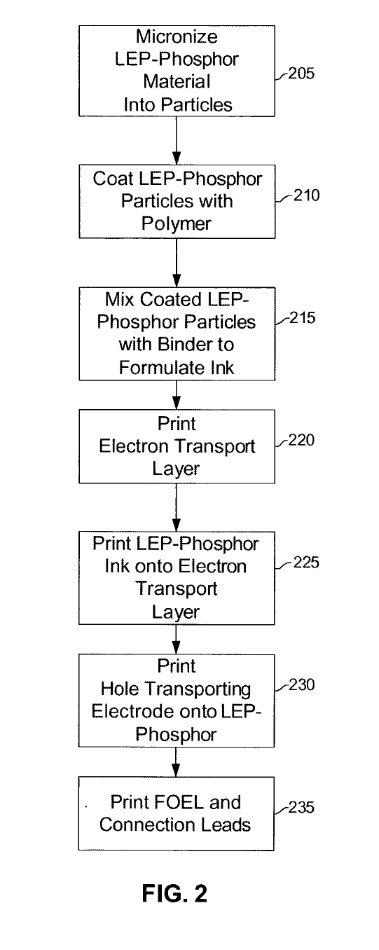

FIG. 2 is a flow chart showing an exemplary sequence of steps for fabricating the electroluminescent panel shown in FIGS. 1A/1B. Fabrication of the present panel 100 is best understood by viewing FIGS. 1A/1B and FIG. 2 in conjunction with one another.

At steps 205 through 220, rear electrode 102 is applied over a front surface of substrate 101. Substrate 101 is formed from a non-conductive transparent material, such as a polyester film, polycarbonate, or other transparent or translucent plastic material.

In an exemplary embodiment, rear electrode 102 is formed of a very thin layer of a conductive material, including metals such as copper, nickel, or platinum, or conductive polymers such as polypyrrole, poly(3,4-ethylenedioxythiophene)(PDOT), poly(3,4-propylenedioxythiophene) (PDOT), or polyphenyleneamineimine, etc. In one embodiment, rear electrode 102 may comprise a conductive polymer such as polypyrrole, poly(3,4-ethylenedioxythiophene) (PDOT), and polyphenyleneamineimine. In an exemplary embodiment, rear electrode 102 has a thickness of between approximately 1 and 10 microns. The examples below illustrate several methods by which rear electrode 102 may be fabricated onto substrate 101.

### EXAMPLE 1

A 2% w/w catalyst solution of palladium acetate (PdAc) ink formulation was prepared by adding 2.6 grams of PdAc (Lot No. 8505047 obtained from APM, Inc.) to 130.6 grams of phosphor binder (available as DuPont KKP415). The catalyst was hand printed (step 205) through a 158 mesh polyester screen using an 80 durometer squeegee onto polycarbonate. The coated sheet was air dried at 285° F. for approximately 5 minutes (step 210). The sheet was immersed in the copper bath for 1 minute (step 215). The sheet was then rinsed and dried (step 220). The sheet resistance was measured with a Prostat® CRS resistance system and found to be 2.38 ohms/square inch.

### EXAMPLE 2

Polycarbonate sheets were subjected to application of the above catalyst by airbrush and electro-deposition of copper as a rear electrode lead 112. The light output of a 15 square inch circle in the design was found to be 27.1 Cd/m2 when a 160 V, 400 Hz square wave signal was applied.

### EXAMPLE 3

The catalyst solution prepared above was printed by hand onto polycarbonate through a 260-mesh screen. In this case a 2-minute exposure in the copper bath yielded a smooth copper film without blisters. The resistance of this sheet was found to be 2.18 ohms/square inch.

### EXAMPLE 4

The same catalyst solution prepared above was hand printed through a 390-mesh screen. In this case, immersion in the copper bath for 45 seconds resulted in a uniform copper coating that was optically transparent. The conductivity was found to be 3.66 ohms/square.

As the above examples illustrate, screen-printing of palladium catalyst in an appropriate binder system may be used to initiate electroless plating of metals in areas where electrode patterns and leads are required in EL devices. It is to be noted that rear electrode layer 102, as well as each of the layers 103-106 that are successively applied in fabricating panel 100, may be applied by any appropriate method, including an ink jet process, a stencil, flat coating, brushing, rolling, spraying, and the like.

Rear electrode layer 102 may cover the entire substrate 101, but this layer 102 typically covers only the illumination area (the area covered by LEP layer 104, described below). Rear electrode lead 112 may be screen printed onto substrate 101, or may be fabricated as an interconnect tab extending beyond the substrate to facilitate connection to a power source or controller.

At step 225, transparent or translucent dielectric layer 103 is applied over rear electrode layer 102. In an exemplary embodiment, dielectric layer 103 comprises a high dielectric constant material, such as a transparent or semi-transparent insulative polymer (for example, polystyrene, polyethylene poly(methyl methacrylate), polyvinylbutyral, polydimethyl siloxane, Teflon®, or polychloroprene, cyanoethylcellulose, and the like) in which may be dispersed a high dielectric constant insulating inorganic material such as silicon dioxide, aluminum oxide, barium titanate, titanium oxide, or strontium titanate. In an exemplary embodiment, dielectric layer 103 may have a thickness of between approximately 0.1 micron and 100 microns. It is preferable also to have the refractive indices of the inorganic filler and the insulating polymer to be as close as possible for improved transmission of light. It is also feasible to employ a binder for the phosphor layer that has a high dielectric constant, such as cyanoethylcellulose, and eliminate the dielectric layer completely¹. ¹Yoshimasa A. Ono, “Electroluminescent Displays” World Scientific, New Jersey, 1995, p. 11.

In accordance with one embodiment, dielectric layer 102 has substantially the same shape as the illumination area, but extends approximately 1/16″ to ⅛″ beyond the illumination area. Alternatively, dielectric layer 102 may cover substantially all of substrate 101.

At step 230, an electroluminescent material is applied over dielectric layer 210 to form illumination layer 104. Illumination layer 104 is formulated in accordance with the process described above with respect to FIGS. 1A, 1B, and 2. The size of the illumination area covered by layer 104 may be any suitable size, with a preferred range from approximately 1 sq. inch to 100 sq. inches. In an exemplary embodiment of the present system, illumination layer 104 comprises light emitting polymers such as such as poly(p-phenylene vinylene) or poly[2-methoxy-5-(2′-ethylhexyloxy)-1,4-phenylenevinylene]. In an alternative, LEP particles comprise OLEDs (organic light emitting devices) such as Tris(8hydroxyquinolato) aluminum, Tetra(2-methyl-8-hydroxyquinolato) boron, and lithium salt. Other suitable light emitting polymers and OLEDs may be employed as provided hereinabove. Light emitting polymers and OLEDs operate off low voltage and are adaptable to being applied in thin layers.

At step 235, translucent or transparent conductive layer 105 is printed over LEP layer 104, extending about 1/16″ to ⅛″ beyond LEP area 104. The distance beyond the Illumination layer to which conductive layer 105 extends is a function of the size of the panel. Accordingly, the extension of conductive layer 105 beyond Illumination area 104 may advantageously be between approximately 2 percent and 10 percent of the width of Illumination layer 104. In an exemplary embodiment, conductive layer 105 comprises indium tin oxide (ITO) particles in the form of a screen printable ink such as DuPont 7160.

In an alternative embodiment, conductive layer may also be formed by the electroless process described above with respect to step 505. Due to the transparent nature of thin electroless coatings, and their relatively high conductivity of <4 ohms/square inch as compared to printed ITO (indium tin oxide) layers having a conductivity of 200 to 1000 ohms/square inch, an electrolessly plated electrode may be used as a replacement for EL device layers previously formed from ITO. In a further alternative embodiment, conductive layer is non-metallic, and comprises a conductive polymer, such as polypyrrole, poly(3,4-ethylenedioxythiophene) (PDOT), poly(3,4-propylenedioxythiophene) (PDOT), or polyphenyleneamineimine. In an exemplary embodiment, an ITO conductive layer 105 may have a thickness of between approximately 2×10⁻⁴ inches and 5×10⁴ inches.

At step 240, a front outlining electrode layer (FOEL) 106, comprising a conductive material such as silver or carbon, is applied onto the outer perimeter of conductive layer 105 to transport energy thereto. Front electrode 106 is typically 1/16″ to ⅛″ wide strip, or approximately 2 percent to 20 percent of the width of conductive layer 105, depending on the current drawn by panel 100 and the length of the panel from the controller or power source. For example, front electrode 106 may be approximately ⅛″ wide for a 50″ wire run from the controller.

Electrode lead 113 may be screen printed onto FOEL 106, or may be fabricated as an interconnect tab extending beyond FOEL to facilitate connection to a power source or controller. In one embodiment, front outlining electrode layer 106 contacts substantially the entire outer perimeter of conductive layer 105 and does not overlap rear electrode 102.

In one embodiment, front electrode 106 contacts only about 25% of outer perimeter of conductive layer 105. Front electrode may be fabricated to contact any amount of the outer perimeter of conductive layer 105 from about 25% to about 100%. Front outlining electrode 106 may, for example, comprise silver particles that form a screen printable ink such as DuPont 7145.

In an alternative embodiment, front outlining electrode 106 is non-metallic and is translucent or transparent, and comprises a conductive polymer, such as polypyrrole, poly(3,4 ethylenedioxythiophene) (PDOT), poly(3,4propylenedioxythiophene) (PDOT), or polyphenyleneamineimine. Fabricating front and rear electrodes 106/102 with polymers such as the aforementioned compounds would make panel 100 more flexible, as well as more durable and corrosion resistant. In an exemplary embodiment, a silver front outlining electrode layer 106 has a thickness of between approximately 8×10⁻⁴ inches and 1.1×10⁻³ inches.

What is claimed is:

1. An electroluminescent light emitting panel that is transparent until illuminated which comprises:
a substrate;
a transparent first electrode layer;
a dielectric layer;
a layer of electroluminescent material;
a transparent second electrode layer; and
a front outlining electrode layer;
wherein the electroluminescent layer:
emits light in the presence of an electrical potential applied to the first electrode layer and to the second electrode layer; and
is transparent in the absence of an electrical potential applied to the first electrode layer and to the second electrode layer.

2. The panel of claim 1 wherein said transparent second electrode layer and said front outlining electrode are the same layer.

3. The panel of claim 1 wherein said electroluminescent material comprises a light emitting polymer selected from the group consisting of poly(p-phenylene vinylene) and poly[2-methoxy-5-(2′-ethylhexyloxy)-1,4-phenylenevinylenei].

4. The panel of claim 1 wherein said electroluminescent material comprises OLEDs (organic light emitting devices) selected from the group consisting of Tris(8-hydroxyquinolato) aluminum, Tetra(2-methyl-8-hydroxyquinolato) boron, and lithium salt.

5. The panel of claim 1 wherein said first electrode layer comprises indium tin oxide (ITO).

6. The panel of claim 1 wherein said second electrode layer comprises indium tin oxide (ITO).

7. The panel of claim 1 wherein said first electrode layer comprises a conductive polymer selected from the group consisting of polypyrrole, poly(3,4-ethylenedioxythiophene) (PDOT), poly(3,4-propylenedioxythiophene) (PDOT), and polyphenyleneamineimine.

8. The panel of claim 1 wherein said second electrode layer comprises a conductive polymer selected from the group consisting of polypyrrole, poly(3,4-ethylenedioxythiophene) (PDOT), poly(3,4propylenedioxythiophene) (PDOT), and polyphenyleneamineimine.

9. The panel of claim 1 wherein said transparent dielectric layer comprises a polymer selected from the group consisting of polystyrene, polyethylene, poly(methyl methacrylate), polyvinylbutyral, polydimethyl siloxane, Teflon®, polychloroprene, and cyanoethylcellulose

10. The panel of claim 1 wherein said transparent dielectric layer further comprises an inorganic material selected from the group consisting of silicon dioxide, aluminum oxide, barium titanate, titanium oxide, and strontium titanate.

11. The panel of claim 1 wherein said front outlining electrode comprises silver or carbon.

12. The panel of claim 1 wherein said front outlining electrode comprises a conductive polymer selected from the group consisting of polypyrrole, poly(3,4-ethylenedioxythiophene) (PDOT), poly(3,4-propylenedioxythiophene) (PDOT), and polyphenyleneamineimine.

13. A method for fabricating an electroluminescent light emitting panel that is transparent until illuminated, said method comprising:
depositing a transparent first electrode layer to a transparent substrate;
depositing a transparent dielectric layer to the first electrode;
depositing a layer of electroluminescent material to the dielectric layer;
depositing a transparent second electrode layer to the layer of electroluminescent material; and
depositing an outlining electrode to the second electrode layer;
wherein the electroluminescent layer:
emits light in the presence of an electrical potential applied to the first electrode layer and to the second electrode layer; and
is transparent in the absence of an electrical potential applied to the first electrode layer and to the second electrode layer.

14. The method of claim 13 wherein said transparent second electrode layer and said front outlining electrode are the same layer.

15. The method of claim 13 wherein any of the depositing steps are performed by a printing process.

16. The method of claim 15 wherein said printing process is selected from the group consisting of electrolessly plating, screen printing, hand printing, and ink jetting.

17. The method of claim 16 wherein said printing process is electroless plating.

18. The method of claim 13 wherein said electroluminescent material comprises a light emitting polymer selected from the group consisting of poly(p-phenylene vinylene) and poly[2-methoxy-5-(2′-ethylhexyloxy)-1,4-phenylenevinylene].

19. The method of claim 13 wherein said electroluminescent material comprises OLEDs (organic light emitting devices) selected from the group consisting of Tris(8-hydroxyquinolato) aluminum, Tetra(2-methyl-8-hydroxyquinolato) boron, and lithium salt.

20. The method of claim 13 wherein said first electrode layer comprises indium tin oxide (ITO).

21. The method of claim 13 wherein said second electrode layer comprises indium tin oxide (ITO).

22. The method of claim 13 wherein said first electrode layer comprises a conductive polymer selected from the group consisting of polypyrrole, poly(3,4-ethylenedioxythiophene) (PDOT), poly(3,4-propylenedioxythiophene) (PDOT), and polyphenyleneamineimine.

23. The method of claim 13 wherein said second electrode layer comprises a conductive polymer selected from the group consisting of polypyrrole, poly(3,4-ethylenedioxythiophene) (PDOT), poly(3,4-propylenedioxythiophene) (PDOT), and polyphenyleneaminei mine.

24. The method of claim 13 wherein said transparent dielectric layer comprises a polymer selected from the group consisting of polystyrene, polyethylene, poly(methyl methacrylate), polyvinylbutyral, polydimethyl siloxane, Teflon®, polychloroprene, and cyanoethylcellulose

25. The method of claim 13 wherein said transparent dielectric layer further comprises an inorganic material selected from the group consisting of silicon dioxide, aluminum oxide, barium titanate, titanium oxide, and strontium titanate.

26. The method of claim 13 wherein said front outlining electrode comprises silver or carbon.

27. The method of claim 13 wherein said front outlining electrode comprises a conductive polymer selected from the group consisting of polypyrrole, poly(3,4-ethylenedioxythiophene) (PDOT), poly(3,4-propylenedioxythiophene) (PDOT), and polyphenyleneamineimine.
